(19) United States
(12) Patent Application Publication
(10) Pub. No.: US 2026/0339802 A1
(43) Pub. Date: Oct. 29, 2026

(54) SYSTEM LOCATION MAPPING BY CHASSIS IDENTITY ALERTING

(71) Applicant: DELL PRODUCTS L.P., Round Rock, TX (US)

(72) Inventors: Christopher Poblete, Austin, TX (US); Marshal Savage, Austin, TX (US)

(21) Appl. No.: 19/190,374

(22) Filed: Apr. 25, 2025

(51) Int. Cl. G06F 11/32; H05K 7/14

(52) U.S. Cl. CPC G06F 11/327; H05K 7/1498

(57) ABSTRACT

An information handling system receives a first physical location of a first system in a data center, receives a first system alert from the first system, receives a second system alert from a second system in the data center, and determines a second physical location of the second system based upon the receipt of the second system alert.

### FIELD OF THE DISCLOSURE

This disclosure relates to information handling systems, and more particularly relates to system location mapping by chassis identity alerting in an information handling system.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

An information handling system may receive a first physical location of a first system in a data center, receive a first system alert from the first system, receive a second system alert from a second system in the data center, and determine a second physical location of the second system based upon the receipt of the second system alert.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a block diagram illustrating a data center according to an embodiment of the present disclosure;

FIG. 2 is a block diagram illustrating an information handling system according to an embodiment of the present disclosure;

FIGS. 3A and 3B illustrate processes for system location mapping by chassis identity alerting in the data center of FIG. 1;

FIG. 4 is a swim lane diagram illustrating a method for system location mapping by chassis identity alerting according to an embodiment of the present disclosure;

FIG. 5 illustrates another process for server rack location mapping by chassis identity alerting in the data center of FIG. 1; and

FIG. 6 is a block diagram illustrating a generalized information handling system according to another embodiment of the present disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

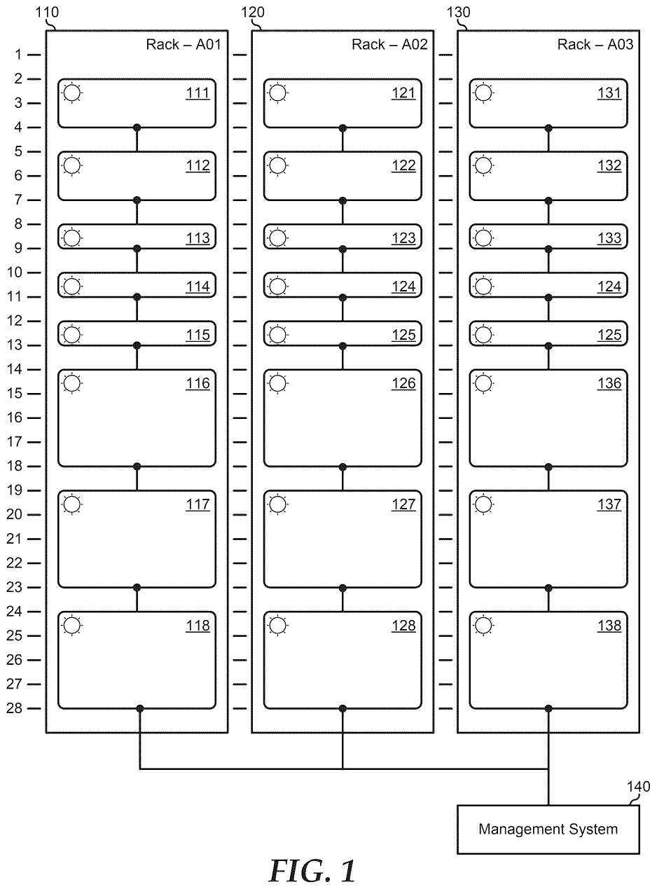

FIG. 1 illustrates a data center 100, including server racks 110, 120, and 130, and a management system 140. Data center 100 represents a facility to house data processing systems such as servers, storage systems, networking equipment, or other equipment, and may represent a single facility or multiple facilities across a variety of locations, as needed or desired. Server racks 110, 120, and 130 represent standardized enclosures for hosing the equipment of data center 100. Server racks 110, 120, and 130 may typically be specified to house equipment that conforms to a particular standard, such as the EIA-310 standard, such as where the equipment housed in the server racks are 19-inches wide, and with heights measured in rack units (U), where 1 U equals 1.75 inches. Server racks 110, 120, and 130 are illustrated as being 28 U high. This is for illustrative purposes, and it will be understood that a typical server rack may have other heights, such as 42 U server racks or 48U server racks. Data center 100 is illustrated as having only three (3) server racks, but this is not necessarily so, and a typical data center may include multiple server racks. For example, an enterprise data center may include 1000-10,000 server racks, while a hyperscale data center may include upwards of 100,000 or more server racks, as needed or desired.

Server rack 110 includes information handling systems 111-118, server rack 120 includes information handling systems 121-128, and server rack 130 includes information handling systems 131-138. As illustrated, server racks 110, 120, and 130 include similarly sized information handling systems in similar locations. For example, server rack 110 includes 2 U information handling system 111 in rack unit location 2, server rack 120 includes 2 U information handling system 121 in rack unit location 2, and server rack 130 includes 2 U information handling system 131 in rack unit location 2. Further, server rack 110 includes a 1 U “padding” between information handling systems 111-118, server rack 120 includes a 1 U “padding” between information handling systems 121-128, and server rack 130 includes a 1 U “padding” between information handling systems 131-138. Such similarity in the arrangement of the information handling systems within server racks in a data center is typical for large numbers of the server racks with the data center, but this is not necessarily so, and other arrangements can be provided as needed or desired. However, even where a data center includes multiple different arrangements of server racks, nevertheless, it is common to see hundreds or even thousands of server racks with identical arrangements within a row of server racks.

Thus, the visual landscape of a typical data center presents a challenge to service technicians when a particular information handling system is in need of service. Information handling systems within a data center typically include an service indicator, such as an amber LED, that indicates that the particular information handling system is in need of service. Moreover, multiple information handling systems within a data center may be in need of service from different service technicians. For example, various clients may have access to service information handling systems leased by the clients, while the operator of the data center may have their own service technicians. In another example, one service technician may be responsible for maintaining power supply units or other power equipment, while another service technician may be responsible for maintaining storage equipment. As such, it becomes difficult for the service technician to visually identify a target information handling system, and the service indicators of all of the information handling systems may appear functionally identical, giving no indication as to whether the information handling system is, for example, in need of servicing for a power supply issue or for a storage element issue.

Information handling systems 111-118, 121-128, and 131-138 are each connected to management system 140. Management system 140 represents an information handling system configured to monitor, manage, and maintain the physical and virtual elements of data center 100. An example of management system 140 may include a system management console, such as an OpenManage Enterprise (OME) console, a Microsoft Management Console (MMC), a Linux Cockpit console, or the like. Management system 140 thus operates to receive monitoring information from information handling systems 111-118, 121-128, and 131-138, such as log and event information, resource utilization information, workload status information, and the like, to send management information to the information handling systems, whereby the management system directs the operations of the information handling systems, and to send maintenance information such as BIOS/UEFI, firmware, or software updates, and the like. Of particular note, information handling systems 111-118, 121-128, and 131-138 operate to provide alert indication information to management system 140 to communicate the nature of any alert conditions on the information handling systems that may have resulted in the illumination of the information handling systems'service indicators.

Information handling systems 111-118, 121-128, and 131-138 may each be identified by one or more unique name within data center 100. For example, a particular information handling system may have a name associated with the overall data center, another name associated with a client, or other names, as needed or desired. When one of information handling systems 111-118, 121-128, and 131-138 issues an alert to management system 140, the alert may be tagged with the one or more name of the information handling system to better identify the particular information handling system that issued the alert. However the service technician's possession of the name of an information handling system may not be sufficient to aid in locating the target information handling system, without having to search, for example, for a sticker affixed to the front or the back of the information handling system.

In a typical data center, the problems identified above may be overcome by manually accessing each information handling system, such as via a service technician crash cart being plugged into the information handling systems one at a time, or via a management system connection to each information handling system one at a time, and then manually loading the associated location information into the associated information handling system. With the location information loaded into each information handling system, a map can be generated of the data center. However, this one-time manual loading of the location information is cumbersome and time consuming. Thus it has been understood by the inventors of the current disclosure that a method of correlating a particular information handling system with an associated physical location within the datacenter may be needed, which, when supplied to the service technician, allows the service technician to quickly locate the target system.

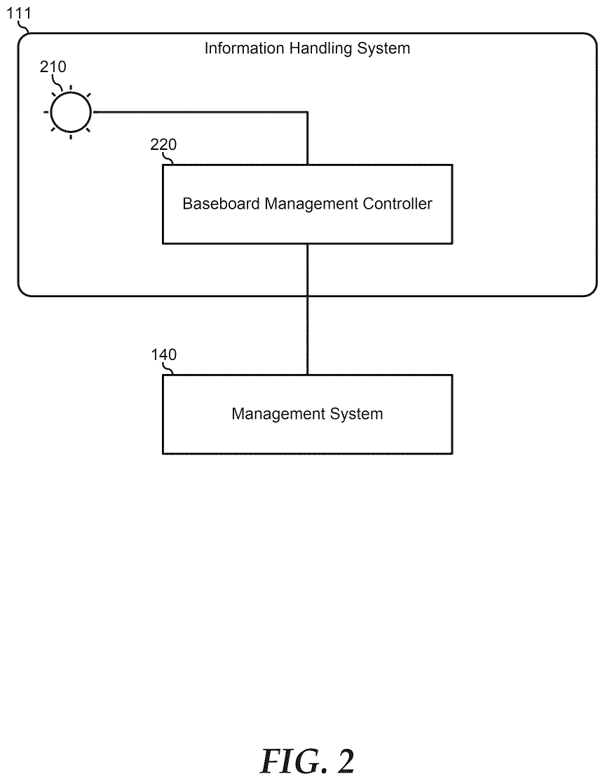

FIG. 2 illustrates information handling system 111 and its connection with management system 140. Information handling system 111 will be understood to be typical of information handling systems 111-118, 121-128, and 131-138, and the functions and features of information handling system 111 as described herein, may be understood to be found implemented on the other information handling systems of data center 100. Information handling system 111 includes a chassis identify button 210 and a baseboard management controller (BMC) 220. Chassis identify button 210 represents a user interface on a front or back side of information handling system 111 that a service technician interacts with to provide a signal to BMC 220. As such, chassis identify button 210 may represent a push-button, a switch, or another device configured to be interacted with by a service technician. In response to receiving the user input to chassis identify button 210, BMC 220 provides identity information for information handling system 111 to management system 140. The identity information may include the one or more system name for information handling system 111, or other information to identify the information handling system.

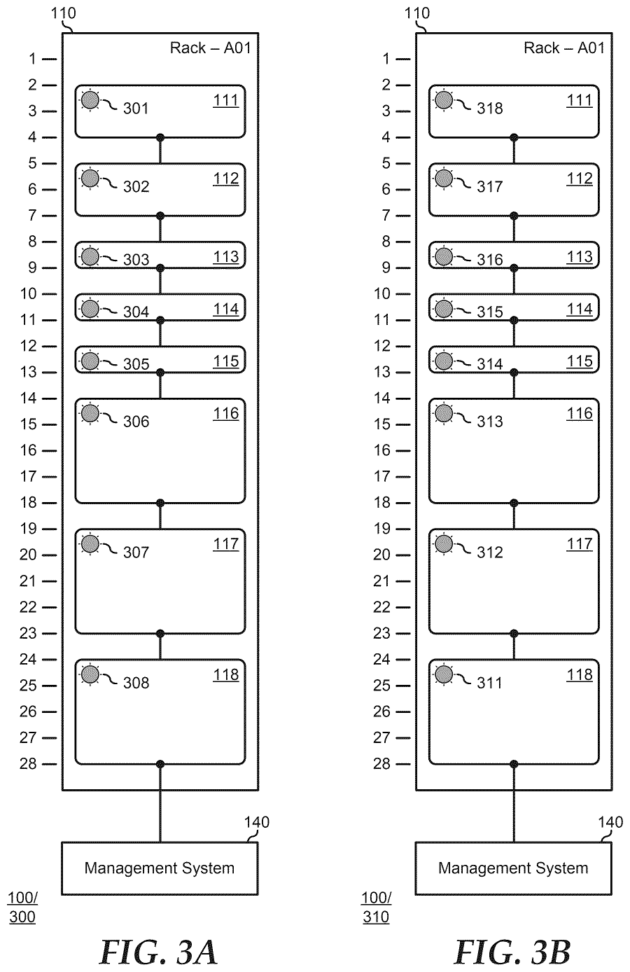

FIG. 3A illustrates a process 300 for system location mapping by chassis identity alerting in data center 100. In a first step of process 300 (not illustrated), a service technician, located proximate to server rack 110, provides a group identifier for information handling systems 111-118. The group identifier may represent a name for a client that is associated with information handling systems 111-118, an identifier for a particular one of multiple data centers, or another group identifier, as needed or desired. Further in the first step, the service technician identifies an initial location (L) of the first information handling system in server rack 110 (i.e., information handling system 111), and a unit padding (P) for the information handling systems in the server rack which represents a number of empty rack units (U) between the information handling systems. Then, in step 301, the service technician activates the chassis identify button of information handling system 111. The service technician waits a predefined interval(S), and then, in step 302, the service technician activates the chassis identify button of information handling system 112.

The process proceeds similarly with the service technician waiting the predefined interval (S) before activating the chassis identify button of information handling system 113 in step 303, the chassis identify button of information handling system 114 in step 304, the chassis identify button of information handling system 115 in step 305, the chassis identify button of information handling system 116 in step 306, the chassis identify button of information handling system 117 in step 307, the chassis identify button of information handling system 118 in step 308, and finally, the chassis identify button of information handling system 119 in step 309. Process 300 may be understood to represent a “forward direction” for system location mapping, where the forward direction is defined as starting with the information handling system at the top of the server rack and moving downward to each adjacent lower information handling system.

FIG. 3B illustrates a process 310 for system location mapping by chassis identity alerting in data center 100. In a first step of process 310 (not illustrated), a service technician, located proximate to server rack 110, provides a group identifier for information handling systems 111-118. The group identifier may represent a name for a client that is associated with information handling systems 111-118, an identifier for a particular one of multiple data centers, or another group identifier, as needed or desired. Further in the first step, the service technician identifies an initial location (L) of the first information handling system in server rack 110 (i.e., information handling system 118), and a unit padding (P) for the information handling systems in the server rack which represents a number of empty rack units (U) between the information handling systems. Then, in step 311, the service technician activates the chassis identify button of information handling system 118. The service technician waits twice the predefined interval (2S), and then, in step 312, the service technician activates the chassis identify button of information handling system 117.

The service technician waits the predefined interval(S), and then, in step 313, the service technician activates the chassis identity button of information handling system 313. The process proceeds similarly with the service technician waiting the predefined interval(S) before activating the chassis identify button of information handling system 115 in step 314, the chassis identify button of information handling system 114 in step 315, the chassis identify button of information handling system 113 in step 316, the chassis identify button of information handling system 112 in step 317, the chassis identify button of information handling system 118 in step 318, and finally, the chassis identify button of information handling system 111 in step 319. Process 310 may be understood to represent a “reverse direction” for system location mapping, where the reverse direction is defined as starting with the information handling system at the bottom of the server rack and moving upward to each adjacent higher information handling system. The interval of twice the predefined interval between steps 311 and 312 operates to identify the process as being the reverse direction process 310.

In both of processes 300 and 310, the predefined interval(S) is selected to permit the service technician to locate the chassis identify button of the next information handling system and to activate the chassis identify button. Thus the predefined interval(S) may be a matter of seconds, such as one (1) second, two (2) seconds, or another interval, as needed or desired. Processes 300 and 310 will be understood to represent the actions of a service technician in system location mapping, and thus FIGS. 3A and 3B will be illustrative of a method for system location mapping as described further below.

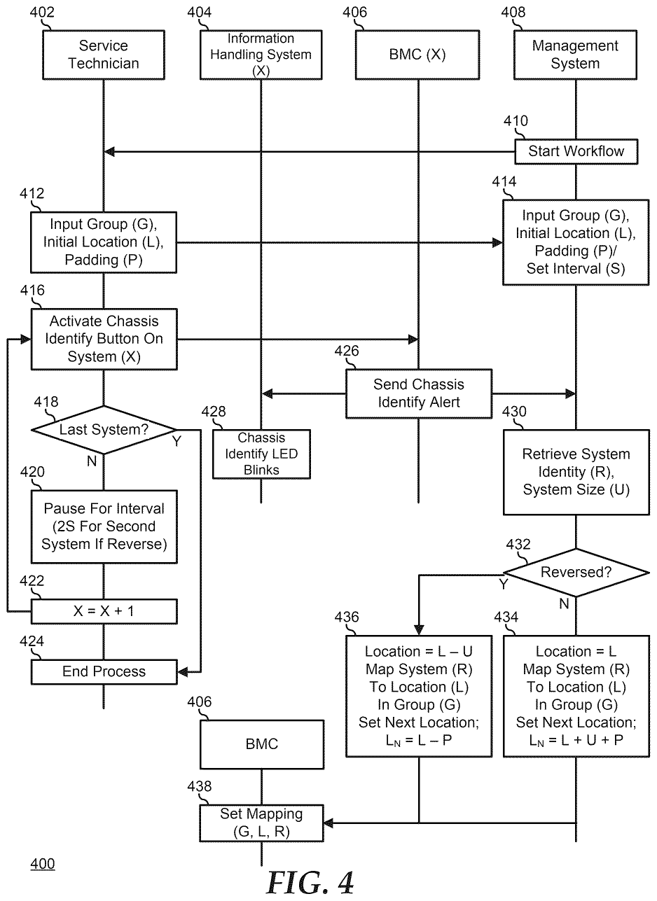

FIG. 4 illustrates a method 400 for system location mapping by chassis identity alerting. In particular, method 400 is a swim lane diagram for the actions of a service technician 402, an information handling system 404, a BMC 406 of the information handling system, and a management system 408. Method 400 starts at step 410 where management system 408 initiates a system location mapping workflow. Service technician 402 may be in communication with management system 408 and receives an indication of the initiation of the workflow. Service technician 402 inputs a group identifier (G), an initial U-location for a first information handling system (L), and a padding number (P) for a particular server rack in a data center, in step 412. In step 414, management system 408 receives the group identifier (G), initial U-location for a first information handling system (L), and padding number (P) for the server rack, and sets the predefined interval(S).

With the above set up steps completed, service technician 402 proceeds with a process such as processes 300 or 310 as described above. In particular, in a step 416, service technician 402 activates a chassis identity button on a first system (X), and the activation of the chassis identity button is provided to BMC 406, as described further below. After activating the chassis identity button, a decision is made as to whether or not the system (X) is the last system to identify in the process in decision step 418. If so, the “Y” branch of decision step 418 is taken and the process ends in step 424. If not, the “N” branch of decision step 418 is taken, and service technician 402 waits for the predefined interval(S), except when the information handling system being identified is a second information handling system identified in the process and the process is a reverse direction process, such as in process 310. In the case where the information handling system being identified is a second information handling system identified in the process and the process is a reverse direction process, service technician 402 waits for twice the predefined interval (2S) in step 420. In either case, the next information handling system is selected in step 422, that is shown formulaically as “X=X+1,” and the process returns to step 416 where service technician 402 activates the chassis identify button of the next information handling system.

For each activation of an information handling system's chassis identity button during the process described above, the associated BMC 406 receives the activation, and sends a chassis identity alert to management system 408 in step 426. In response to the chassis identify alert, the associated information handling system 404 responds to the chassis identity alert by blinking a chassis identify LED in step 428, and management system 408 retrieves the system identity (R) and the system Size (U) from BMC 406 in step 430. A decision is made as to whether or not the process as described above is a reverse direction process in decision step 432. If not, the “Y” branch of decision step 432 is taken, the location of the information handling system (X) is determined as the current value of (L), management system 408 maps the identified system (R) to the location (L), and the group (G), and sets the location (L) as the next location where L_{N}=L+U+P in step 434, and the management system provides the mapping (G, L, R) to BMC 406 in step 438. If the process is not a reverse direction process, the “Y” branch of decision step 432 is taken, the location of the information handling system (X) is determined as the current value of (L) minus the U-height of the information handling system (L=L−U), management system 408 maps the identified system (R) to the location (L), and the group (G), and sets the location (L) as the next location where L_{N}=L−P in step 436, and the management system provides the mapping (G, L, R) to BMC 406 in step 438.

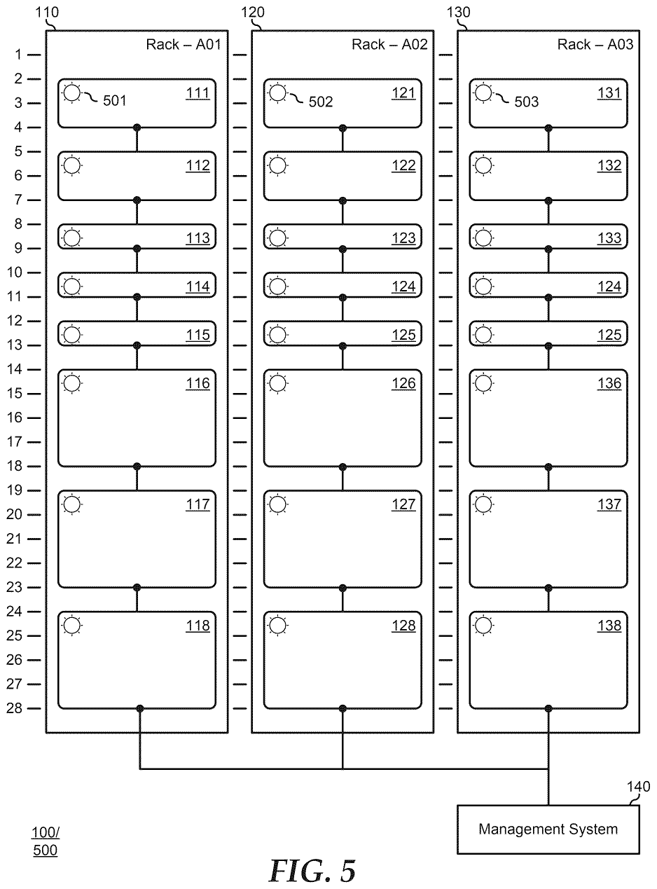

FIG. 5 illustrates a process 500 for server rack location mapping by chassis identity alerting in data center 100. In a first step of process 500 (not illustrated), a service technician, located proximate to server rack 110, provides a group identifier for server racks 110, 120, and 130. Further in the first step, the service technician identifies a first information handling system in server rack 110 (i.e., information handling system 111). Then, in step 501, the service technician activates the chassis identify button of information handling system 111. The service technician waits a predefined interval(S), and then, in step 502, the service technician activates the chassis identify button of information handling system 121. Finally, the service technician waits the predefined interval(S), and, in step 503, the service technician activates the chassis identify button of information handling system 130. A method similar to method 400 may be provided for mapping server racks 110, 120, and 130 as adjacent server racks within data center 100.

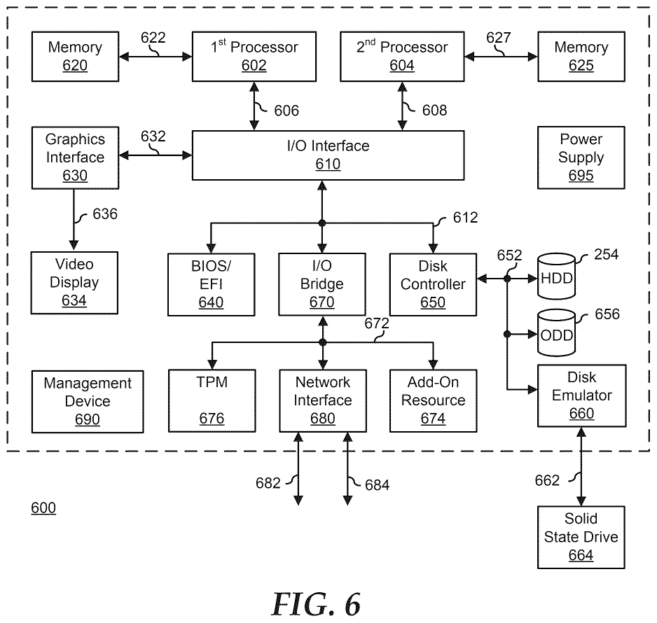

FIG. 6 illustrates a generalized embodiment of an information handling system 600 similar to information handling system 600. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 600 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 600 can include processing resources for executing machine-executable code, such as a central processing unit (CPU), a programmable logic array (PLA), an embedded device such as a System-on-a-Chip (SoC), or other control logic hardware. Information handling system 600 can also include one or more computer-readable medium for storing machine-executable code, such as software or data. Additional components of information handling system 600 can include one or more storage devices that can store machine-executable code, one or more communications ports for communicating with external devices, and various input and output (I/O) devices, such as a keyboard, a mouse, and a video display. Information handling system 600 can also include one or more buses operable to transmit information between the various hardware components.

Information handling system 600 can include devices or modules that embody one or more of the devices or modules described below, and operates to perform one or more of the methods described below. Information handling system 600 includes a processors 602 and 604, an input/output (I/O) interface 610, memories 620 and 625, a graphics interface 630, a basic input and output system/universal extensible firmware interface (BIOS/UEFI) module 640, a disk controller 650, a hard disk drive (HDD) 654, an optical disk drive (ODD) 656, a disk emulator 660 connected to an external solid state drive (SSD) 662, an I/O bridge 670, one or more add-on resources 674, a trusted platform module (TPM) 676, a network interface 680, a management device 690, and a power supply 695. Processors 602 and 604, I/O interface 610, memory 620, graphics interface 630, BIOS/UEFI module 640, disk controller 650, HDD 654, ODD 656, disk emulator 660, SSD 662, I/O bridge 670, add-on resources 674, TPM 676, and network interface 680 operate together to provide a host environment of information handling system 600 that operates to provide the data processing functionality of the information handling system. The host environment operates to execute machine-executable code, including platform BIOS/UEFI code, device firmware, operating system code, applications, programs, and the like, to perform the data processing tasks associated with information handling system 600.

In the host environment, processor 602 is connected to I/O interface 610 via processor interface 606, and processor 604 is connected to the I/O interface via processor interface 608. Memory 620 is connected to processor 602 via a memory interface 622. Memory 625 is connected to processor 604 via a memory interface 627. Graphics interface 630 is connected to I/O interface 610 via a graphics interface 632, and provides a video display output 636 to a video display 634. In a particular embodiment, information handling system 600 includes separate memories that are dedicated to each of processors 602 and 604 via separate memory interfaces. An example of memories 620 and 630 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 640, disk controller 650, and I/O bridge 670 are connected to I/O interface 610 via an I/O channel 612. An example of I/O channel 612 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 610 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 640 includes BIOS/UEFI code operable to detect resources within information handling system 600, to provide drivers for the resources, initialize the resources, and access the resources. BIOS/UEFI module 640 includes code that operates to detect resources within information handling system 600, to provide drivers for the resources, to initialize the resources, and to access the resources.

Disk controller 650 includes a disk interface 652 that connects the disk controller to HDD 654, to ODD 656, and to disk emulator 660. An example of disk interface 652 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 660 permits SSD 664 to be connected to information handling system 600 via an external interface 662. An example of external interface 662 includes a USB interface, an IEEE 1394 (Firewire) interface, a proprietary interface, or a combination thereof. Alternatively, solid-state drive 664 can be disposed within information handling system 600.

I/O bridge 670 includes a peripheral interface 672 that connects the I/O bridge to add-on resource 674, to TPM 676, and to network interface 680. Peripheral interface 672 can be the same type of interface as I/O channel 612, or can be a different type of interface. As such, I/O bridge 670 extends the capacity of I/O channel 612 where peripheral interface 672 and the I/O channel are of the same type, and the I/O bridge translates information from a format suitable to the I/O channel to a format suitable to the peripheral channel 672 where they are of a different type. Add-on resource 674 can include a data storage system, an additional graphics interface, a network interface card (NIC), a sound/video processing card, another add-on resource, or a combination thereof. Add-on resource 674 can be on a main circuit board, on separate circuit board or add-in card disposed within information handling system 600, a device that is external to the information handling system, or a combination thereof.

Network interface 680 represents a NIC disposed within information handling system 600, on a main circuit board of the information handling system, integrated onto another component such as I/O interface 610, in another suitable location, or a combination thereof. Network interface device 680 includes network channels 682 and 684 that provide interfaces to devices that are external to information handling system 600. In a particular embodiment, network channels 682 and 684 are of a different type than peripheral channel 672 and network interface 680 translates information from a format suitable to the peripheral channel to a format suitable to external devices. An example of network channels 682 and 684 includes InfiniBand channels, Fibre Channel channels, Gigabit Ethernet channels, proprietary channel architectures, or a combination thereof. Network channels 682 and 684 can be connected to external network resources (not illustrated). The network resource can include another information handling system, a data storage system, another network, a grid management system, another suitable resource, or a combination thereof.

Management device 690 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 600. In particular, management device 690 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 600, such as system cooling fans and power supplies. Management device 690 can include a network connection to an external management system, and the management device can communicate with the management system to report status information for information handling system 600, to receive BIOS/UEFI or system firmware updates, or to perform other task for managing and controlling the operation of information handling system 600. Management device 690 can operate off of a separate power plane from the components of the host environment so that the management device receives power to manage information handling system 600 where the information handling system is otherwise shut down. An example of management device 690 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 690 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed:

1. An information handling system, comprising:
a memory device to store code; and
a processor to execute code to:
receive a first physical location of a first system in a data center;
receive a first system alert from the first system;
receive a second system alert from a second system in the data center; and
determine a second physical location of the second system based upon the receipt of the second system alert.

2. The information handling system of claim 1, wherein the processor is further to provide a predefined interval(S).

3. The information handling system of claim 2, wherein determining the second physical location is in response to receiving the second system alert within the predefined interval (S) of receiving the first system alert.

4. The information handling system of claim 3, wherein the processor is further to determine that the first physical location is at a top of a first server rack of the data center based upon receiving the second system alert within the predefined interval(S) of receiving the first system alert.

5. The information handling system of claim 2, wherein determining the second physical location is in response to receiving the second system alert within twice the predefined interval (2S) of receiving the first system alert.

6. The information handling system of claim 5, wherein the processor is further to determine that the first physical location is at a bottom of a first server rack of the data center based upon receiving the second system alert within twice the predefined interval (2S) of receiving the first system alert.

7. The information handling system of claim 1, wherein the processor is further to retrieve a first system identity from the first system in response to receiving the first system alert, and to retrieve a second system identity from the second system in response to receiving the second system alert.

8. The information handling system of claim 7, wherein the processor is further to map the first system identity to the first physical location, and to map the second system identity to the second physical location.

9. The information handling system of claim 8, wherein the processor is further to provide a first mapping of the first system identity to the first physical location to the first system, and to provide a second mapping of the second system identity to the second physical location to the second system.

10. The information handling system of claim 1, wherein the information handling system includes a data center management system.

11. A method, comprising:
receiving, by an information handling system, a first physical location of a first system in a data center;
receiving, by the information handling system, a first system alert from the first system;
receiving, by the information handling system, a second system alert from a second system in the data center; and
determining, by the information handling system, a second physical location of the second system based upon the receipt of the second system alert.

12. The method of claim 11, further comprising providing a predefined interval(S).

13. The method of claim 12, wherein determining the second physical location is in response to receiving the second system alert within the predefined interval(S) of receiving the first system alert.

14. The method of claim 13, further comprising determining that the first physical location is at a top of a first server rack of the data center based upon receiving the second system alert within the predefined interval(S) of receiving the first system alert.

15. The method of claim 12, wherein determining the second physical location is in response to receiving the second system alert within twice the predefined interval (2S) of receiving the first system alert.

16. The method of claim 15, further comprising determining that the first physical location is at a bottom of a first server rack of the data center based upon receiving the second system alert within twice the predefined interval (2S) of receiving the first system alert.

17. The method of claim 11, further comprising:
retrieving a first system identity from the first system in response to receiving the first system alert; and
retrieving a second system identity from the second system in response to receiving the second system alert.

18. The method of claim 17, further comprising:
mapping the first system identity to the first physical location; and
mapping the second system identity to the second physical location.

19. The method of claim 18, further comprising:
providing first mapping of the first system identity to the first physical location to the first system; and
providing a second mapping of the second system identity to the second physical location to the second system.

20. An information handling system, comprising:
a memory device to store code; and
a processor to execute code to:
receive a first physical location of a first system in a data center;
receive a first system alert from the first system;
retrieve a first system identity from the first system in response to receiving the first system alert;
map the first system identity to the first physical location;
receive a second system alert from a second system in the data center within a predefined interval of receiving the first system alert;
retrieve a second system identity from the second system in response to receiving the second system alert;
determine a second physical location of the second system based upon the receipt of the second system alert; and
map the second system identity to the second physical location.
